(19) United States
(12) Patent Application Publication
(10) Pub. No.: US 2010/0001353 A1
(43) Pub. Date: Jan. 7, 2010

(54) SANOS Memory Cell Structure

(75) Inventor: Fumitake MIENO, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 12/259,065

(22) Filed: Oct. 27, 2008

(30) Foreign Application Priority Data
Jul. 3, 2008 (CN) 200810040291.1

(51) Int. Cl. H01L 29/786; H01L 21/336

(52) U.S. Cl. 257/411; 438/287; 257/E21.409; 257/E29.292

(57) ABSTRACT

A semiconductor device having a silicon-aluminum oxide-nitride-oxide-semiconductor (SANOS) memory cell structure is provided. The device includes a silicon substrate including a surface, a source region and a drain region in the surface. The drain region and the source region are separate from each other. The device further includes a confined dielectric structure on the surface and between the source region and the drain region. The confined dielectric structure includes sequentially a silicon oxide layer, a silicon nitride layer, and an aluminum oxide layer. Additionally, the device includes a gate region overlying the aluminum oxide layer. In a specific embodiment, the gate region is made from patterning an amorphous silicon layer. In another specific embodiment, the gate region includes a polysilicon layer. In an alternative embodiment, a method of making the same memory cell structure is provided and can be repeated to integrate the structure three-dimensionally or embedded for system-on-chip applications.

### CROSS-REFERENCE TO RELATED APPLICATIONS

This application claims priority to Chinese Patent Application No. 200810040291.1, filed Jul. 3, 2008, commonly assigned, and incorporated herein by reference for all purposes.

### BACKGROUND OF THE INVENTION

The present invention is directed to integrated circuits and their processing for the manufacture of semiconductor devices. More particularly, the invention provides a semiconductor device having a non-volatile flash memory cell and a method for making the device. Merely by way of example, the invention has been applied to a silicon-aluminum oxide-nitride-oxide-silicon (SANOS) memory cell structure and a method for making the memory cell structure. But it would be recognized that the invention has a much broader range of applicability. For example, the invention can be applied to a variety of devices such as dynamic random access memory devices, static random access memory devices, flash memory devices, embedded system-on-chip applications, three-dimensional memory array, and others.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed.

As an example, for non-volatile flash memory devices oxide-nitride-oxide (ONO) dielectrics as charge trapping memory layer has been proposed for the future high density memory application. Using insulating nitride film to store the charge is much more reliable than convention conductor floating gate, especially when there are defects in the oxide layer. However, the development is hindered by the data retention characteristics when scaling down the memory cell size. In particular, the total oxide thickness is desired to be reduced so that a smaller voltage can produce the same programming electric field. At the same time, the retention time of the trapped charges is desired to be the same if not longer as the cell size scales down. One feasible solution is to replace the block oxide layer by a high permittivity (high-k) material with large barrier height. Thus, the equivalent total oxide thickness can be reduced while the trapping property is not sacrificed due to the thinner physical thickness.

From the above, it is seen that an improved technique for processing semiconductor devices, including the use of high-k dielectrics in memory cell, is desired.

### BRIEF SUMMARY OF THE INVENTION

The present invention is directed to integrated circuits and their processing for the manufacture of semiconductor devices. More particularly, the invention provides a semiconductor device having a non-volatile flash memory cell and a method for making the device. Merely by way of example, the invention has been applied to a silicon-aluminum oxide-nitride-oxide-silicon (SANOS) memory cell structure and a method for making the memory cell structure. But it would be recognized that the invention has a much broader range of applicability. For example, the invention can be applied to a variety of devices such as dynamic random access memory devices, static random access memory devices, flash memory devices, embedded system-on-chip applications, three-dimensional memory array, and others.

In a specific embodiment, the invention provides a method of making a silicon-aluminum oxide-nitride-oxide-silicon (SANOS) memory cell structure. The method includes providing a silicon substrate which has a surface region. The method further includes forming a multilayer including silicon oxide layer, a silicon nitride layer, an aluminum oxide layer, and a gate layer sequentially grown on the surface region. Additionally, the method includes patterning and etching the multilayer to form a confined structure beyond which the surface region is revealed; the confined structure including the gate layer capable of forming a gate electrode. Moreover, the method includes forming a source region and a drain region in the surface region. The source region and the drain region are separate from each other located at opposite sides of the confined structure.

In another specific embodiment, the invention provides a semiconductor device having a SANOS memory cell structure. The device includes a silicon substrate having a surface. Additionally, the device includes a source region and a drain region in the surface. The drain region and the source region being separate from each other. The device further includes a confined dielectric structure on the surface and between the source region and the drain region. The confined dielectric structure includes sequentially a silicon oxide layer, a silicon nitride layer, and an aluminum oxide layer. Moreover, the device includes a gate region overlying the aluminum oxide layer.

In yet another specific embodiment, a multilayer film is formed using cluster tools to deposit the different layers separately without atmosphere exposure. the combination of silicon oxide, silicon nitride, and aluminum oxide in a confined dielectric layered structure is capable of forming a highly reliable charge storing element with a reduced equivalent total oxide thickness (EOT). In one embodiment, the method of making SANOS memory cell structure is compatible with standard CMOS technology based on cluster tools for sequential multilayer deposition and capable of scaling down and stacking integration three dimensionally. Furthermore, in another embodiment, the SANOS memory cell structure can be embedded for system-on-chip applications.

Many benefits can be achieved by way of the present invention over conventional techniques. According to certain embodiments, the present invention combines the advantages of high reliability of silicon nitride layer for charge-trapping with a high-k aluminum oxide layer as gate blocking oxide, small geometric cell size and simple layered structure, and low thermal budget for fabrication and dopant activation within temperature ranges tolerated by the memory cell. In addition, the present invention provides a simple process that is compatible with conventional CMOS process technology without substantial modifications to conventional equipment and processes. In certain embodiments, the method provides a process to form a multilayer films deposited using low-pressure atomic-layer deposition (ALD) based on cluster tools. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified side-view diagram of a SANOS memory cell according to an embodiment of the present invention;

FIG. 2 is a simplified diagram showing a method of manufacturing a SANOS memory cell structure according to an embodiment of the present invention;

FIGS. 3A is a simplified diagram showing a method of providing a silicon substrate for making a SANOS memory cell structure according to an embodiment of the present invention;

FIGS. 3B through 3D is a simplified diagram showing a method of forming a multilayer dielectric film on the silicon substrate for making a SANOS memory cell structure according to an embodiment of the present invention;

FIG. 3E is a simplified diagram showing a method of forming a gate layer for making a SANOS memory cell structure according to an embodiment of the present invention;

FIG. 3F is a simplified diagram showing a method of patterning and etching the multilayer dielectric film to form a confined structure including a gate electrode for making a SANOS memory cell structure according to an embodiment of the present invention;

FIG. 3G is a simplified diagram showing a method of forming a source region and a drain region for making a SANOS memory cell structure according to an embodiment of the present invention;

FIG. 3H is a simplified diagram showing a method of adding a dielectric spacer for making a SANOS memory cell structure according to an embodiment of the present invention.

### DETAILED DESCRIPTION OF THE INVENTION

The present invention is directed to integrated circuits and their processing for the manufacture of semiconductor devices. More particularly, the invention provides a semiconductor device having a non-volatile flash memory cell and a method for making the device. Merely by way of example, the invention has been applied to a silicon-aluminum oxide-nitride-oxide-silicon (SANOS) memory cell structure and a method for making the memory cell structure. But it would be recognized that the invention has a much broader range of applicability. For example, the invention can be applied to a variety of devices such as dynamic random access memory devices, static random access memory devices, flash memory devices, embedded system-on-chip applications, three-dimensional memory array, and others.

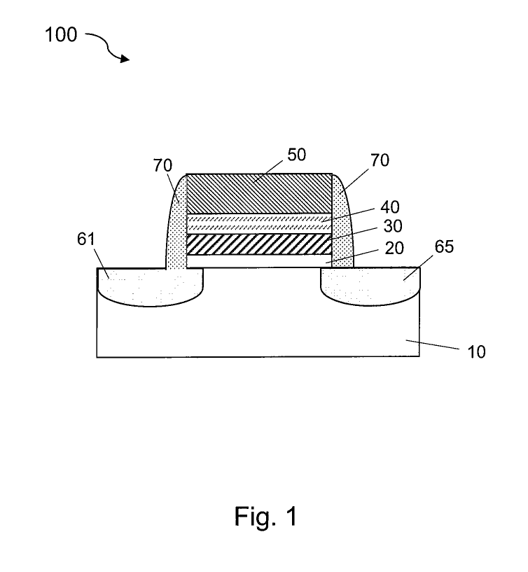

FIG. 1 is a simplified diagram for a semiconductor device 100 with a SANOS memory cell structure that is capable of being embedded or stacked three-dimensionally. This diagram is merely an example, which should not unduly limit the scope of the claims. One of ordinary skill in the art would recognize many variations, alternatives, and modifications. The device 100 includes following components:

1. Silicon substrate 10;

2. Silicon oxide layer 20;

3. Silicon nitride layer 30;

4. Aluminum oxide layer 40;

5. Gate layer 50;

6. Source region 61;

7. Drain region 65; and

8. Spacer region 70.

Although the above has been shown using a selected group of components for the device 100, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particular below.

In one embodiment, the silicon substrate 10 is an active layer being lightly doped. For example, the silicon substrate is a processed silicon-on-insulator (SOI) wafer. In another example, the surface of the silicon substrate 10 is processed with a wet treatment using combination of the standard cleaning solution (SC-1: mixture of H₂O₂, NH₄, and H₂O) and diluted HF acid. In one embodiment, the substrate is a hydrogen-terminated surface. In another embodiment, the substrate is an oxygen-terminated surface after wet treatment using SC-2 (mixture of H₂O₂, HCl, and H₂O) solution at a final step.

Referring to FIG. 1, the silicon oxide layer 20 overlays on the substrate 10 in a confined region. In one embodiment, the silicon oxide layer 20, which is referred to as gate oxide, comprises silicon dioxide formed through thermal oxidation process on the silicon substrate 10. In another embodiment, the silicon oxide layer 20 is a thin silicon dioxide layer of about 2.5 nm deposited by atomic layer deposition (ALD).

Silicon nitride layer 30, as shown in FIG. 1, is located on the silicon oxide layer 20. In one embodiment, the silicon nitride layer 30 is an ALD or CVD deposited thin film with a thickness about 12 nm. Sequentially, the aluminum oxide layer 40 overlays the silicon nitride layer 30 and the gate layer 50 locates on the aluminum oxide layer 40. In one embodiment, the aluminum oxide layer is an ALD deposited thin film of about 10 nm. In another embodiment, the gate layer is a silicon layer of about 150 nm. The gate layer, in one specific embodiment, is made of amorphous silicon (a-Si) formed with a LPCVD process at relatively low temperature (about 560° C. or lower) and low pressure at about 0.2 Torr. In the LPCVD process, group III or V impurities are added through corresponding precursor gases to make the gate layer a highly doped to either p-type or n-type amorphous silicon layer. In another specific embodiment, the gate layer is made of polycrystalline silicon formed with a similar LPCVD process but at a higher temperature (570-620° C.). Again, the polysilicon gate layer can be doped within the same LPCVD process. For example, the gate layer 50 is a highly doped N⁺ polysilicon layer for an n-type SANOS memory cell. In another example, the gate layer 50 can be a highly doped P⁺ polysilicon layer for an p-type SANOS memory cell.

As seen in FIG. 1, all these sequential layers are confined with a similar geometry or pattern of the silicon oxide layer 20 on the silicon substrate 10. In one embodiment, the first three layers (20, 30, and 40) forms a confined dielectric layered structure which is similar to conventional oxide-nitride-oxide (ONO) layer as a charge trapping element for a memory cell. Additionally, the dielectric layered structure in device 100 advantageously replaces the top silicon oxide block layer with a high-k aluminum oxide layer, enhancing the charge retention and reducing the gate leakage current with a reduced equivalent total oxide thickness (EOT). Other high-k dielectric materials such as titanium oxide, hafnium oxide, zirconium oxide, etc. may be used in place of the aluminum oxide layer 40. Of course, one of ordinary skilled in the art would recognize that many alternatives, modifications, and variations may be applicable for selecting the gate dielectric materials as the memory cell scaling down.

Referring again to FIG. 1, the source region 61 and drain region 65 are located within the substrate 10 and at the two opposite sides of the confined layer structure. The source region and the drain region are formed through a ion-plantation specifically towards those surface regions after a proper device masking. In one embodiment, the source and drain regions are heavily doped with group III impurity ions to p-type for a p-SANOS memory cell with a n-type substrate. The corresponding gate electrode may be made of P⁺ polysilicon layer. In another embodiment, the source and drain regions are heavily doped with group V impurity ions to n-type for a n-SANOS memory cell with a p-type substrate. The corresponding gate electrode may be made of N⁺ polysilicon layer.

Furthermore, as shown in FIG. 1, a dielectric spacer 70 may be placed at the interface between either the source region 61 or drain region 65 and the confined layer structure (20, 30, and 40) plus the gate electrode 50. The dielectric spacer 70 is used, as in many conventional memory devices, as an insulation isolator for the source/drain regions and the gate region. Therefore, the device 100 is a complete silicon-aluminum oxide-nitride-oxide-semiconductor (SANOS) memory cell. It can be a n-type SANOS cell, or a p-type SANOS cell.

According to an embodiment of the present invention, the device 100 with a SANOS memory cell structure can be repeated laterally to form a memory array. The memory array further can be passivated with an inter-layer dielectrics with a plurality of metal interconnects and/or contacts to the gate, source or drain regions. In another embodiment, the passivation layer can be further planarized to form a substrate for stacking or direct making a plurality of the devices 100 again. In yet another embodiment, the present invention provides a SANOS memory cell structure that can be integrated in multiple layers to form a three-dimensional memory array.

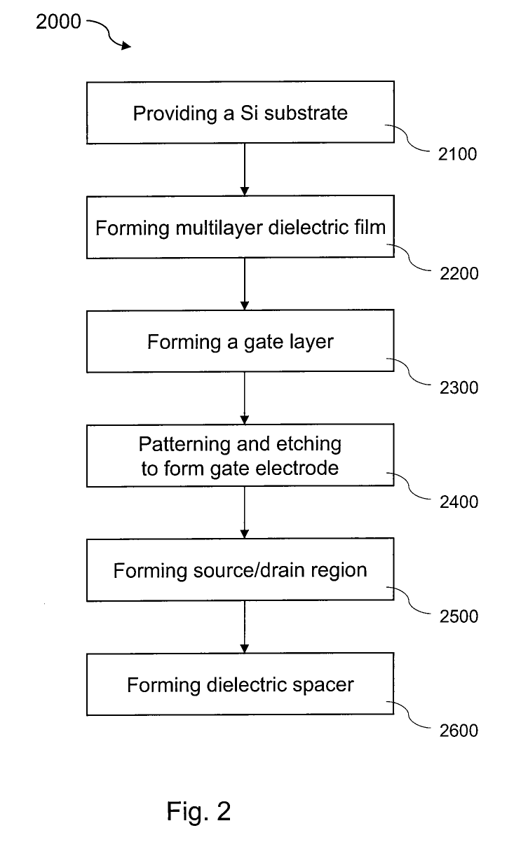

FIG. 2 is a simplified diagram showing a method for manufacturing a SANOS memory cell structure according to an embodiment of the present invention. This diagram is merely an example, which should not unduly limit the scope of the claims herein. The method 2000 includes the following processes:

1. Process 2100 for providing a silicon substrate;

2. Process 2200 for forming a multilayer dielectric film including sequentially a silicon oxide layer, a silicon nitride layer, and an aluminum oxide layer;

3. Process 2300 for forming a gate layer;

4. Process 2400 for patterning and etching to form a gate electrode overlying a confined multilayer dielectric film;

5. Process 2500 for forming source and drain regions; and

6. Process 2600 for forming dielectric spacer.

The above sequence of processes provides a method according to an embodiment of the present invention. Other alternatives can also be provided where processes are added, one or more processes are removed, or one or more processes are provided in a different sequence without departing from the scope of the claims herein. For example, the semiconductor device with a SANOS memory cell structure made by the method 2000 is the device 100. Further details of the present invention can be found throughout the present specification and more particularly below.

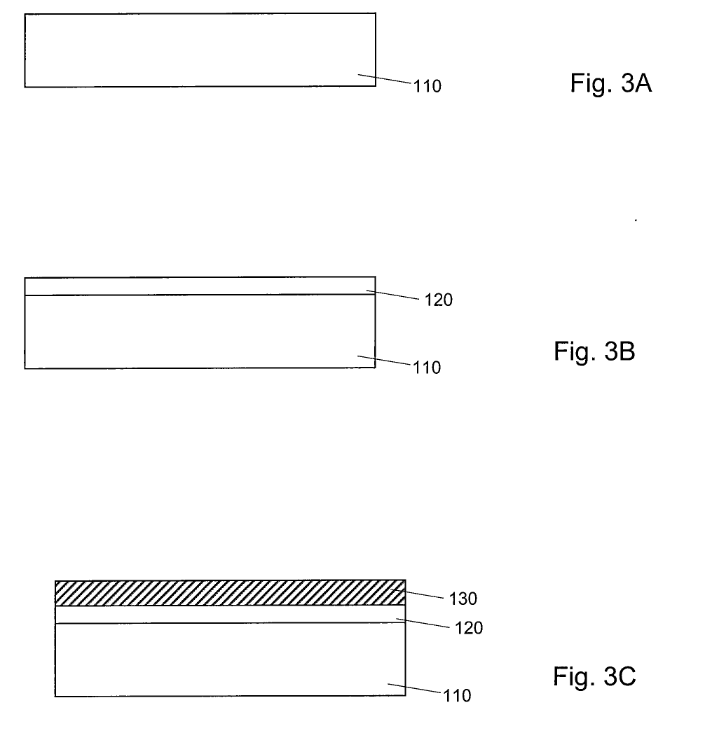

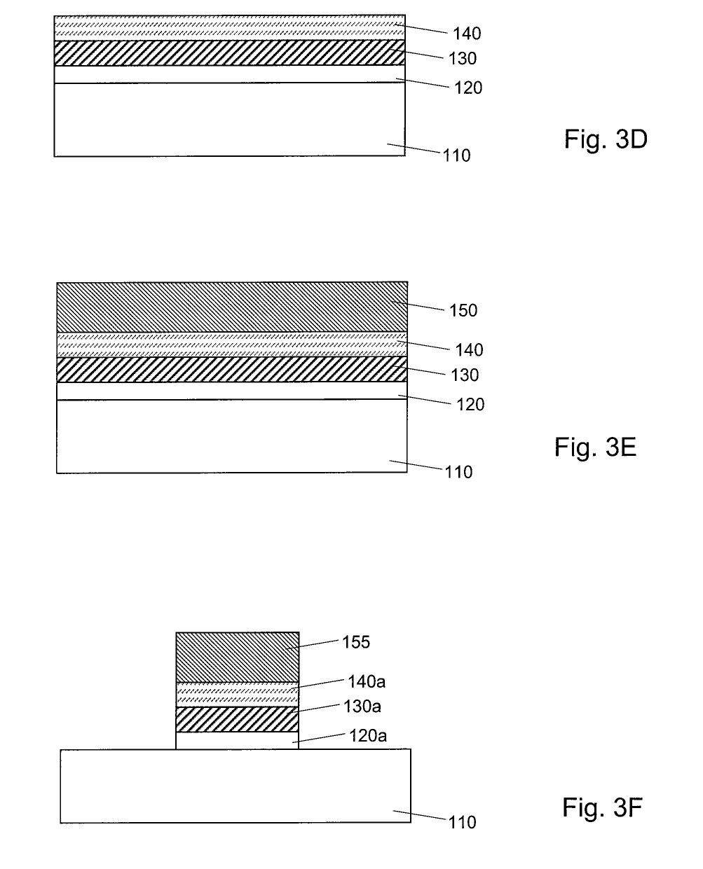

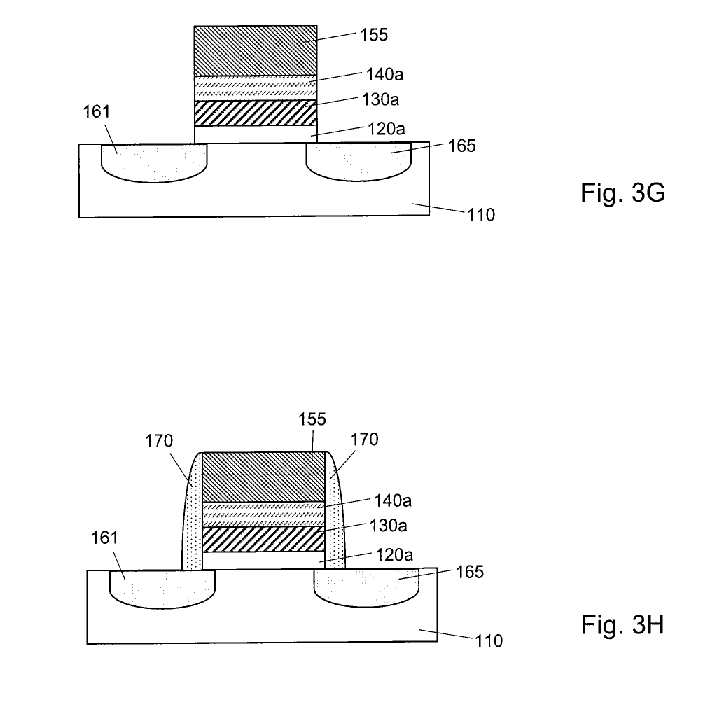

At the process 2100, a silicon substrate is provided. FIG. 3A shows a simplified method for providing a silicon substrate for manufacturing a semiconductor device with a SANOS memory cell structure according to an embodiment of the present invention. This diagram is merely an example, which should not unduly limit the scope of the claims. One of ordinary skill in the art would recognize many variations, alternatives, and modifications.

As shown in FIG. 3A, a substrate 110 is provided. For example, the particular substrate 110 includes single crystalline silicon. The silicon substrate can be an active layer processed with a light impurity doping. The doping polarity may be p-type or n-type, being selected for making n-type SANOS memory cell structure or p-type SANOS memory cell structure. In another example, the substrate 110 includes a plurality of other semiconductor materials including germanium, silicon carbide, silicon germanium, or group III/V compound semiconductors. In a specific embodiment, the substrate can be an active single crystalline SOI layer of a silicon-on-insulator wafer. In another specific embodiment, the substrate can includes a single crystalline silicon layer over a plurality of memory devices embedded in inter-layer dielectrics with passivation.

Once the substrate 110 is provided, a wet surface treatment is performed. In one embodiment, the wet treatment process involves of using a standard cleaning solution SC-1 which has a formulation of 1:1:5 ratio of NH₄OH, H₂O₂, and dionized water. Dilute formulation may be used too. The treatment is usually performed at about 70° C. The SC-1 treatment usually creates a rough and a thinly-oxidized surface. After the SC-1 treatment, the substrate is dipped to a diluted hydrofluoric acid HF solution to have certain etching of the silicon oxide and further removing certain insoluble metal particles, leading to a surface mostly terminated with hydrogen. In another embodiment, a further surface treatment will be performed using SC-2 solution at typical 70° C. after the diluted hydrofluoric acid HF dipping. The SC-2 cleaning solution has a formulation of 1:1:5 of HCl, H₂O₂, and dionized water (or diluted version with less HCl and H₂O₂). The SC-2 treatment further dissolves alkali ions and their hydroxides, and desorbs residual metallic contaminants. This treatment leaves a thin oxidized or oxygen terminated surface. According to certain embodiments, dionized water rinse may be applied before, in between, or after those surface treatments. Finally, spin rinse dry is performed and the substrate 110 is ready for film deposition.

Referring back to FIG. 2 at process 2200, a multilayer dielectric film is formed on the cleaned substrate 110. FIGS. 3B, 3C, and 3D show a simplified method for forming a multilayer dielectric film for manufacturing a semiconductor device with SANOS memory cell structures according to an embodiment of the present invention. These diagrams are merely examples, which should not unduly limit the scope of the claims. One of ordinary skill in the art would recognize many variations, alternatives, and modifications. For example, the process 2200 can be implemented to make the device 100.

Firstly, as shown in FIG. 3B, a silicon oxide layer 120 is grown on the substrate 110. In an embodiment, the silicon oxide layer 120 may be formed by a thermal oxidation process. For example, it may be a dry oxidation process with lower temperature for better thickness control. In another example, it may be a wet oxidation process which is faster than dry process. A rapid thermal processing tool may be required to achieve desired heating ramp rate for ultra thin oxide layer formation. The thermal oxidation process in fact forms a layer of silicon oxide 120 out of the original silicon substrate.

In a specific embodiment, the silicon oxide layer 120 is formed by depositing SiO₂ from silene SiH₄ and nitric oxide NO gas or pure oxygen O₂ gas with an ALD process. The ALD process is performed in one of cluster tools in a low pressure environment. For example, during the process precursor gases such as silene SiH₄ and/or nitric oxide NO, are used and the deposition is assisted with O₂ 2 slm remote plasma. For example, in a certain preferred process, SiH₄ flow rate is chosen to be about 300 sccm. The process chamber is controlled to be a 0.2 Torr low pressure environment and the substrate temperature is controlled at about 450° C. With O₂ remote plasma, chemically active oxygen species (such as O₂ metastables or O atoms) interact with the silicon substrate 110 so that an ultra thin (a few atomic layers) oxide passivating layer of SiO₂ is created at the surface of the substrate, which prevents the substrate from further oxidation by the ALD process. Then the ALD-deposited SiO₂ gate oxide layer is formed on the surface with precise thickness control. For example, the silicon oxide layer 120, i.e., the gate oxide, may be controlled to be only about 2.5 nm or less in thickness for device 100. In another embodiment, adding nitric oxide NO as ALD precursor gas helps to induce an interfacial nitridation between the silicon substrate 110 and silicon oxide layer 120. The interfacial nitridation has two important aspects of device reliability and performance: improvement of hot-carrier and current-stress reliability, and reduction of direct and Fowler-Nordheim (F-N) tunneling currents. After the SiO2 deposition, certain rapid thermal annealing process may be performed to reduce oxidation-induced sub-oxide bonding at Si—SiO₂ interface and to promote densification of the oxide film.

Secondly, as shown in FIG. 3C, a silicon nitride layer 130 is formed overlying the silicon oxide layer 120. In one embodiment, deposition of the silicon nitride layer 130 may be performed in a same process chamber for silicon oxide layer deposition but with NH₄ 1 slm remote plasma instead of O₂ remote plasma. In another embodiment, deposition of the silicon nitride layer may be performed in a neighboring chamber where the substrate 110 with just grown silicon oxide layer 120 can be transferred through a vacuum interlock without atmosphere exposure. The silicon nitride layer 130, according to a specific embodiment, is deposited from silene SiH₄ with an ALD process assisted by NH₄ 1 slm remote plasma. For example, in a certain preferred process, SiH₄ flow rate is chosen to be about 500 sccm with a working environment of about 0.15 Torr pressure and about 450° C. In another example, post-deposition annealing with a rapid thermal processing tool may be performed at temperature up to 900° C. These process condition yields a low-defect-density silicon nitride film with reliable electrical performance as charge trapping element for the memory cell. In one example, the silicon nitride layer 130 is controlled to about 12 nm in thickness for the device 100.

Subsequently, as shown in FIG. 3D, an aluminum oxide layer 140 is grown over the silicon nitride layer 130 to complete the sequential multilayer dielectric film growth. In a specific embodiment, deposition of the aluminum oxide layer 140 is performed in a neighboring chamber of the cluster deposition tools where the substrate 110 with just grown silicon oxide layer 120 followed by silicon nitride layer 130 can be transferred through a vacuum interlock without atmosphere exposure. In one embodiment, the deposition of aluminum oxide film is performed using an ALD process. For example, during the process a trimethyl aluminum (TMA) liquid source bubbling through nitrogen N₂ gas with a flow rate of about 300 sccm and gas precursor O₃ flowing in about 300 sccm through the chamber at the same time. In another example, the chamber pressure is controlled to about 0.10 Torr and deposition temperature is controlled at about 450° C. In yet another example, the thickness of the aluminum oxide layer 140 can be controlled to be about 10 nm for device 100. In another embodiment, the aluminum oxide layer serves a gate blocking dielectric or control oxide for the charges stored in the silicon nitride layer. Because of its higher dielectric constant and work function, the gate leakage would be suppressed and charge retention time of the memory device thus is improved. In yet another embodiment, the combination of the silicon oxide layer 120, silicon nitride layer 130, and aluminum oxide layer 140 may be engineered and adjusted to achieve an optimum equivalent total oxide thickness for the memory cell. Other high-k dielectric materials such as titanium oxide, hafnium oxide, zirconium oxide, etc. may be used in place of the aluminum oxide layer. Of course, one of ordinary skilled in the art would recognize that many alternatives, modifications, and variations may be applicable for selecting the gate dielectric materials as the memory cell scaling down.

Referring again to FIG. 2, at process 2300 a gate layer is formed. FIG. 3E shows a simplified method for forming a gate layer for manufacturing a semiconductor device with SANOS memory cell structures according to an embodiment of the present invention. These diagrams are merely examples, which should not unduly limit the scope of the claims. One of ordinary skill in the art would recognize many variations, alternatives, and modifications. For example, the process 2300 can be implemented to make the device 100.

As shown in FIG. 3E, the gate layer 150 is grown on the aluminum oxide layer 140. The gate layer is a highly doped semiconductor layer, which is yet conductive and capable of forming a gate for the SANOS memory cell. In one specific embodiment, the gate layer 140 is an amorphous silicon (a-Si) layer highly doped with group III or V impurities. For example, the a-Si layer is formed by depositing a-Si from precursor gas silene SiH₄ in a LPCVD process with the pressure controlled to be about 0.2 Torr and the temperature being set at below 560° C. (typically within the range of 520-560° C.). In another example, the doping process is performed at the same time with the LPCVD film deposition process wherein certain precursor gases containing the doping elements such as boron or phosphorus are introduced into the chamber and mixed with SiH₄ precursor gas for a-Si deposition. The doping level for the gate layer would be determined by controlling the flow rates of doping gases such as B₂H₆ or PH₃ in the CVD process. In another example, subsequent film may be annealed using a rapid thermal process. The annealing temperature should also be controlled within 560° C.

In another specific embodiment, the gate layer 140 is an polycrystalline silicon (polysilicon) layer highly doped with group III or V impurities. Similarly, a LPCVD process is used to deposit polysilicon layer from SiH₄ gas precursor and certain doping gases (such as B₂H₆ or PH₃) at low pressure (for example 0.2 Torr) and with temperature controlled in 570-620 Degrees Celsius. In one example, N⁺ polysilicon layer in a thickness of about 150 nm is formed as the gate layer 150 for device 100.

Following FIG. 2 at process 2400, patterning and etching is performed to create a gate electrode overlying a confined multilayer dielectric film. FIG. 3F shows a simplified method for forming a gate electrode overlying a confined dielectric multilayer film for manufacturing a semiconductor device with SANOS memory cell structures according to an embodiment of the present invention. These diagrams are merely examples, which should not unduly limit the scope of the claims. One of ordinary skill in the art would recognize many variations, alternatives, and modifications.

At process 2400, as shown in FIG. 3F, a gate electrode 155 overlying a confined dielectric film is formed by photolithography patterning process followed by a plasma assisted etching process. The patterning and etching processes include known methods such as applying photoresist layer, masking the pre-defined gate structure, exposing UV light, developing the exposed resist, striping exposed resist residue, etching the polysilicon and dielectric layer beyond the defined gate region, and removing resist layer, etc. In one embodiment, the etching process would be stopped at the original silicon substrate by a pre-added etch-stop layer. Therefore, beyond the confined multilayer film structure, all the deposited dielectric or gate layers are completely removed. The confined multilayer film structure includes, from the top to bottom, the gate electrode 155 made from the gate layer 150, the blocking dielectric 140a made from the aluminum oxide layer 140, the trapping layer 130a made from the silicon nitride layer 130, and the tunnel oxide 120a made from the silicon oxide layer 120. Of course, one of ordinary skill in the art would recognize many variations, alternatives, and modifications in specific process steps or their orders in forming a gate electrode overlying a confined dielectric multilayer film for manufacturing a semiconductor device with SANOS memory cell structures.

Referring to FIG. 2, at process 2500 source region and drain region are formed. FIG. 3G shows a simplified method for forming a source region and a drain region for manufacturing a semiconductor device with SANOS memory cell structures according to an embodiment of the present invention. These diagrams are merely examples, which should not unduly limit the scope of the claims. One of ordinary skill in the art would recognize many variations, alternatives, and modifications. For example, the process 2500 can be implemented to make the device 100.

As shown in FIG. 3G, the formation of the gate electrode overlying a confined multilayer dielectric film structure automatically defines two opposite sides thereof. In one embodiment, process 2500 starts with masking the confined structure and all substrate surface except two surface regions in the vicinity of said two opposite sides of the confined structure. Then ion-implantation technique is used to dope group III or V ions into the two open surface regions down to certain depth (also laterally to certain degree by diffusion) of the silicon substrate. For example, ion species like As, B, or P etc. are typically used for doping through ion-implantation. In another example, ion-beam current up to 10 mA at an energy up to 200 keV may be used. With the control of the ion beam current and irradiation time, certain dose and distribution of the impurities in the regions can be achieved. Additionally, certain post-implantation annealing with a rapid thermal processing equipment is performed for restoring the crystalline structure and activate the implanted impurity atoms. In a specific embodiment shown in FIG. 3F, two highly doped regions are formed, including the source region 161 and the drain region 165 depending on the device circuit applications. Depending one the n-type or p-type substrate, the source region 161 and the drain region 165 may be doped to p⁺ type or n⁺ type.

At process 2600, a dielectric spacer is formed. FIG. 3H shows a simplified method for forming a dielectric spacer between the source/drain regions and the gate for manufacturing a semiconductor device with SANOS memory cell structures according to an embodiment of the present invention. These diagrams are merely examples, which should not unduly limit the scope of the claims. One of ordinary skill in the art would recognize many variations, alternatives, and modifications.

In an embodiment, a dielectric spacer 170 for the memory cell can be added, as shown in FIG. 3H, to isolate the source region 161 and the drain region 165 from the gate electrode 155 plus all the sides of the multilayer dielectric film structure. In one embodiment, the dielectric spacer is made of an ONO layer, i.e., oxide-nitride-oxide dielectrics. For example, LPCVD technique may be used to form such a dielectric spacer for the memory cell. In another embodiment, proper pre-deposition masking and resist removing after deposition may be carried out for the formation of spacer 170. Of course, one of ordinary skill in the art may recognize many variations, alternatives, and modifications for this process.

The processes described above for manufacturing a semiconductor device with SANOS memory cell structures are merely examples which should not unduly limit the scope of the claims herein. There can be many alternatives, modifications, and variations for an ordinary skill in the art. For example, some of the processes may be expanded and/or combined. Other processes may be inserted to those mentioned above. According to a specific embodiment, the method 2000 straightforwardly provides a two-dimensional array of memory cells having the same structure of device 100. According to another specific embodiment, the method 2000 can be repeated to stack the memory cell structure in multi-layers to form a three-dimensional (3D) memory array. The simplicity of the formation of a layered a-Si or polysilicon gate electrode over a multilayer dielectric memory storing element on an activated silicon substrate provides fully compatibility with the existing CMOS manufacturing technology and easy 3D stackability. For example, the device 100 having SANOS memory cell structure can be embedded for system-on-chip applications with only addition of 2 or 3 masks.

As shown in FIG. 3H, in a specific embodiment, the invention provides a device with SANOS memory cell structures. The device includes a silicon substrate having a surface. Additionally, the device includes a source region and a drain region in the surface. The drain region and the source region being separate from each other. The device further includes a confined dielectric structure on the surface and between the source region and the drain region. The confined dielectric structure includes sequentially a silicon oxide layer, a silicon nitride layer, and an aluminum oxide layer. Moreover, the device includes a gate region overlying the aluminum oxide layer.

The present invention has various advantages. Some embodiments of the present invention provide a SANOS memory cell structure that is capable for 3D integration. Certain embodiments of the present invention provide a multilayer dielectric film including high-k aluminum oxide as the blocking dielectric in the memory cell to enhance memory device reliability. Particularly, the equivalent total oxide thickness can be reduced to achieve better access time and at the same time the gate current leakage is reduced and charge retention is improved. Some embodiments provide advantage of a simple layered manufacture process for easy device scaling or embedding. Particularly, certain embodiments of the present invention provide a simple method that is fully compatible with established CMOS manufacture technology for making 3D SANOS memory array or system-on-chip with the embedded SANOS memory cell.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of making a silicon-aluminum oxide-nitride-oxide-silicon (SANOS) memory cell structure, the method comprising:
providing a silicon substrate, the silicon substrate having a surface region;
forming a multilayer dielectric film including silicon oxide layer, a silicon nitride layer, and an aluminum oxide layer sequentially on the surface region;
forming a gate layer overlying the aluminum oxide layer;
patterning and etching the multilayer dielectric film and the gate layer to form a confined structure beyond which the surface region is revealed; the confined structure including a gate electrode over the multilayer dielectric film; and
forming a source region and a drain region in the surface region, the source region and the drain region being separate from each other located at opposite sides of the confined structure.

2. The method of claim 1 wherein the silicon substrate may be lightly doped with group III or V impurities.

3. The method of claim 1 wherein the silicon substrate may be an activate silicon-on-insulator (SOI) substrate.

4. The method of claim 1 further comprising performing surface treatments on the surface region with standard clean 1 (SC-1) solution (a mixture of H₂O₂, NH₄OH, and dionized water) followed by diluted hydrofluoric acid (HF) dipping.

5. The method of claim 4 wherein the surface region after surface treatments is hydrogen-terminated.

6. The method of claim 1 further comprising performing surface treatments on the surface region with standard clean 1 (SC-1) solution (a mixture of H₂O₂, NH₄OH, and dionized water) followed by diluted hydrofluoric acid (HF) dipping and then treated by standard clean 2 (SC-2) solution (a mixture of HCl, H₂O₂, and dionized water).

7. The method of claim 6 wherein the surface region after surface treatments is oxygen-terminated.

8. The method of claim 1 wherein forming the multilayer dielectric film further comprises:
forming a silicon oxide layer overlying the surface region;
forming a silicon nitride layer overlying the silicon oxide layer; and
forming an aluminum oxide layer overlying the silicon nitride layer.

9. The method of claim 8 wherein forming a silicon oxide layer overlying the surface region comprises performing an atomic layer deposition (ALD) process.

10. The method of claim 9 wherein the ALD process further comprises depositing silicon dioxide from a precursor gas silene (SiH₄) with a flow rate about 300 sccm under O₂ 2 slm remote plasma environment at about 450° C. and 0.2 Torr pressure.

11. The method of claim 9 wherein the silicon oxide layer is associated with a thickness ranging from 1 nm to 3 nm.

12. The method of claim 9 wherein the ALD process comprises using silene SiH₄ and nitric oxide NO as precursors.

13. The method of claim 8 wherein forming a silicon nitride layer overlying the silicon oxide layer comprises depositing silicon nitride from SiH₄ flowing in about 500 sccm and NH₄ flowing in about 1 slm by ALD technique under a remote plasma environment at about 450° C. and 0.15 Torr pressure.

14. The method of claim 13 wherein the silicon nitride layer is associated with a thickness ranging from 7 nm to 17 nm.

15. The method of claim 8 wherein forming an aluminum oxide layer overlying the silicon nitride layer comprises depositing Al₂O₃ from liquid trimethyl aluminum (TMA) source bubbling with about 300 sccm N₂ gas and with O₃ flowing in about 300 sccm by ALD technique at about 450° C. and 0.10 Torr pressure.

16. The method of claim 15 wherein the aluminum oxide layer is associated with a thickness ranging from 5 nm to 15 nm.

17. The method of claim 1 wherein forming a gate layer overlying the aluminum oxide layer comprises depositing about 150 nm amorphous silicon layer from SiH₄ as precursor by a LPCVD process at about 520-560° C. and about 0.2 Torr pressure.

18. The method of claim 17 wherein the amorphous silicon layer may be highly doped with group III (or V) impurity by adding sufficient gas precursors containing corresponding group III (or V) elements in the LPCVD process.

19. The method of claim 1 wherein forming a gate layer overlying the aluminum oxide layer comprises depositing about 150 nm polycrystalline silicon layer from SiH₄ as precursor by a LPCVD process at 570-620° C. and about 0.2 Torr pressure.

20. The method of claim 19 wherein the polycrystalline silicon layer may be a highly doped P⁺ (or N⁺) polysilicon layer by adding sufficient gas precursors containing corresponding group III (or V) elements in the LPCVD process.

21. The method of claim 1 wherein forming the multilayer dielectric film including the silicon oxide, silicon nitride, and aluminum oxide and forming the gate layer are performed in cluster deposition tools without exposure to atmosphere between deposition steps.

22. The method of claim 1 wherein forming the source region and drain region is performed by ion-implantation with a proper masking.

23. The method of claim 22 wherein the source region and the drain region comprises highly doped group V (or III) impurities for a substrate lightly doped by group III (or V) impurities.

24. A semiconductor device having a SANOS memory cell structure, the device comprising:
a silicon substrate including a surface;
a source region in the surface;
a drain region in the surface, the drain region and the source region being separate from each other;
a confined dielectric structure on the surface and between the source region and the drain region, the confined dielectric structure including sequentially a silicon oxide layer, a silicon nitride layer, and an aluminum oxide layer; and
a gate region overlying the aluminum oxide layer.

25. The method of claim 24 wherein the silicon substrate may be an SOI wafer.

26. The device of claim 24 wherein the silicon substrate may be lightly doped with group III or V impurities.

27. The device of claim 24 wherein the surface of the silicon substrate is hydrogen terminated after a wet treatment with SC-1 solution and diluted HF.

28. The device of claim 24 wherein the surface of the silicon substrate is oxygen terminated after a wet treatment with SC-1 solution, diluted HF, followed by SC-2 solution.

29. The device of claim 24 wherein the source region and the drain region are highly doped with group V (or III) impurities by ion-implantation in the silicon substrate which is lightly doped with group III (or V) impurities.

30. The device of claim 24 wherein the confined dielectric structure including sequentially a silicon oxide layer, a silicon nitride layer, and an aluminum oxide layer comprises a tunnel oxide, a memory storing element, and a blocking dielectric, respectively.

31. The device of claim 30 wherein the silicon oxide layer comprises an about 2.5 nm SiO₂ film formed by thermal oxidation of the silicon substrate.

32. The device of claim 30 wherein the silicon oxide layer comprises an about 2.5 nm ALD-deposited silicon dioxide film located on the surface of the silicon substrate.

33. The device of claim 30 wherein the silicon nitride layer comprises an about 12 nm ALD-deposited SiN film overlying the silicon oxide layer.

34. The device of claim 30 wherein the aluminum oxide layer comprises an about 10 nm ALD-deposited Al₂O₃ film overlying the silicon nitride layer.

35. The device of claim 24 wherein the gate region is made from a gate layer overlying the aluminum oxide layer within the confined structure.

36. The device of claim 35 wherein the gate layer comprises an about 150 nm amorphous silicon film deposited using LPCVD technique at about 520-560° C. and 0.2 Torr pressure.

37. The device of claim 35 wherein the gate layer comprises an about 150 nm polycrystalline silicon film deposited using LPCVD technique at about 570-620° C. and 0.2 Torr pressure.

38. The device of claim 24 wherein the gate region is doped heavily with group III (or V) impurities in case when the source region and the drain region are doped with group V (or III) impurities.

39. The device of claim 24 further comprising a dielectric spacer region for isolating the source region and drain region from the confined dielectric structure and the gate region.
